(19) United States
(12) Patent Application Publication
(10) Pub. No.: US 2013/0112964 A1
(43) Pub. Date: May 9, 2013

(54) AMPHIPHILIC PROTEIN IN PRINTED ELECTRONICS

(71) Applicants: Silke Koehler, Basel (CH); Marcel Kastler, Basel (CH); Georg Schmidt, Chemnitz (DE); Matthias Bartzsch, Halle (DE)

(72) Inventors: Silke Koehler, Basel (CH); Marcel Kastler, Basel (CH); Georg Schmidt, Chemnitz (DE); Matthias Bartzsch, Halle (DE)

(73) Assignee: BASF SE, Ludwigshafen (DE)

(21) Appl. No.: 13/809,496

(22) PCT Filed: Jul. 14, 2011
(86) PCT No.: PCT/EP2011/062018

§ 371 Date: Jan. 10, 2013

Related U.S. Application Data
(60) Provisional application No. 61/369,086, filed on Jul. 30, 2010.

(30) Foreign Application Priority Data
Jul. 30, 2010 (EP) 10171386.5

(51) Int. Cl. H01L 51/00

(52) U.S. Cl. 257/40; 530/350; 438/99

(57) ABSTRACT

Disclosed is a method for preparing an organic electronic device, which contains one or more layers of a suitable functional material on a substrate, which process is characterized in that at least one interlayer of an amphiphilic protein is placed between adjacent layers of the functional material, or between the substrate and the adjacent layer of the functional material. The protein interlayer improves the adhesion of layers without negative impact on the device's performance.

Present invention relates to a process for preparing organic electronic devices having improved performance (especially mechanical adhesion of layers), corresponding devices comprising an amphiphilic protein (especially hydrophobin) interlayer, and the use of an amphiphilic protein for improving the layer adhesion and performance of an organic electronic device.

Amphiphilic proteins such as hydrophobins have already been proposed as adhesion promoting agent in some technical applications (WO06/103225). Zhao et al., Biosens. and Bioelectronics 22, 3021 (2007), disclose the application of a hydrophobin interlayer between electrode and β-D-glucose oxidase for the fabrication of an amperometric glucose biosensor.

NL-A-8105001 proposes the application of an alpha-helical protein in the active layer of a photovoltaic cell.

It has now been found that adhesion of layers in organic electronic devices may be distinctly enhanced by admitting interlayers of an amphiphilic protein, without negative impact on the device's performance.

The present invention thus primarily pertains to a process for the preparation of an organic electronic device comprising one or more layers of suitable functional materials on a substrate, which process is characterized in that at least one interlayer of an amphiphilic protein is placed between adjacent layers of functional materials, or between the substrate and the adjacent layer of a functional material.

The functional materials employed as layers, or patterned layers, in the organic electronic devices of the invention generally are selected from semiconductors, dielectrics, electrochromics and conductors. The substrate is different from the functional material in terms of composition and especially thickness; for example, the substrate material is not a semiconductor. Neither substrate nor functional material is a protein. The substrate typically is selected from inert material providing mechanical strength and protection against chemical and/or physical attack of the device and functional layers; it may be glass, and often is a flexible plastics material; for certain applications like photovoltaics, the substrate is transparent. In order to provide its function, it generally has a thickness of more than 1 micrometer, e.g. 1 micrometer up to several millimeters. Flexible plastics for the purpose often have a thickness from the range 1-1000 micrometer, especially 10-800 micrometer, particularly 50-500 micrometer.

The layer(s) of functional material and/or the amphiphilic protein layer(s) are preferably applied by means of solution processing, e.g. by an ink-jet, screen, gravure, reverse gravure, offset, flexographic printing method. Of special technical importance is a roll-to-roll printing process.

As used herein, “solution-processing” refers to various solution-phase processes including spin-coating, printing (e.g., inkjet printing, screen printing, pad printing, offset printing, gravure printing, flexographic printing, lithographic printing, mass-printing and the like), spray coating, electrospray coating, drop casting, dip coating, and blade coating.

The layer(s) of functional material, especially dielectrics and semiconductors, generally are thin layers below one micrometer, typically ranging from monomolecular layers (or, in the case of metal conductors, monoatomic layers) up to a thickness of several hundred nanometers, e.g. 5-800 nm, or 20-600 nm. Conducting layers, especially of metal conductors, alternatively may be of higher thickness, e.g. up to 5 micrometer, or about 800-3000 nm. Common layer thicknesses of functional material are from the range 40-100 nm.

The amphiphilic protein layer is advantageously obtained after applying an aqueous solution or dispersion of the protein, which preferably contains the protein in an amount ranging from approximately 0.001% to about 1% by weight. The solution or dispersion is preferably applied by a printing method as described above, or by spraying, dipping, doctor blading, curtain coating, slot dye coating, spin coating. A preferred process applies the protein in an amount which allows it to self-assemble to a molecular monolayer. For best formation of the protein layer, the wet layer thus obtained is allowed to settle for about 1 to 10000 s, especially about 10 to 1000 s, e.g. at ambient temperature or elevated temperatures up to 80° C., for example 40-80° C. Subsequently, the amphiphilic protein layer usually is allowed to dry, e.g. at 20 to 160° C., preferably 40 to 120° C. Drying may be enforced and accelerated by application of reduced pressure or by a gas stream.

The amphiphilic protein used in the process of the invention is preferably a hydrophobin. Useful hydrophobins (including fusion products), and their preparation, are disclosed, for example, in WO 06/082253, WO06/103225, WO 07/14897.

The interlayer containing (and preferably consisting of) the amphiphilic protein usually is a molecular monolayer.

The surface active properties of proteins onto substrates can be assessed by interfacial tension measurements, characterization of oil-in-water emulsions and contact angles with water. The amphiphilic protein useful in the present invention is characterized by strongly lowering the contact angle of water (WCA) on a hydrophobic surface (e.g. the surface of a polyolefin or a Teflon® surface). Specifically, a 1% b.w. aqueous solution or dispersion of the amphiphilic protein useful in the present invention generally shows a contact angle on a polypropylen surface (specifically: PP homopolymer type HC115MO, Borealis, melt flow rate=4.0 g/10 min [230° C./2.16 kg]) which is lower than the contact angle observed for pure water by 20 degrees or more, preferably 30 degrees or more, more preferably 40 degrees or more, most preferably 45 degrees or more, and in some specific cases 50 degrees or more (see also FIG. 8 of WO10/003811; all WCA measurements according to static sessile drop method).

The amphiphilic protein is preferably a hydrophobin. In the following, the term “protein” will be used for the amphiphilic protein in general, and specifically for hydrophobin.

For preparation of the interlayer, a solution of the protein is usually employed, e.g. in form of an aqueous solution containing about 0.01 mg/ml to 50 mg/ml of the protein. The solution may contain further ingredients such as water miscible solvents like alcohols, ethers, esters, ketones, e.g. methanol, ethanol, propanol, acetone; also possible are buffer substances and/or surfactants. Of special importance is a solution containing the protein in purified form.

The skilled person will choose a suitable method for preparing the interlayer. For example, the object to be coated can be immersed in the formulation or the formulation can be applied to the surface by spraying on. Sheet-like substrates such as panels or films may advantageously be treated by coating or roller application. Preferred methods also are solvent processing and printing techniques. Excess formulation can be removed once again by means of suitable methods, for example by means of doctoring-off. The coating can preferably be performed by means of spraying. The skilled person is familiar with suitable spraying appliances. Preferred methods for applying the protein layer include spin coating, dip coating, doctor blading, reverse gravure coating, ink jet printing, flexo printing, gravure printing, dye transfer printing.

As a rule, a certain exposure time is required for the proteins to settle on the surface, preferably forming the desired monolayer. The skilled person will choose a suitable exposure time in dependence on the desired result. Examples of typical exposure times are from 0.1 to 12 h, without the invention having to be restricted to these times.

In order to facilitate formation of the desired thin layer, especially the molecular monolayer of the protein, excess protein solution is advantageously removed while the coating is still wet, e.g. by spinning, or advantageously by rinsing with a suitable solvent such as water, a water miscible solvent (e.g. alcohol, ester etc. as mentioned above), or a mixture of such solvents.

As a rule, the exposure time depends on the temperature and on the concentration of the protein in the solution. The higher the temperature and the higher the concentration during the course of the coating process, the shorter the exposure time may be. The temperature during the course of the coating process can be room temperature, or else it can be an elevated temperature. For example, possible temperatures are 5, 10, 20, 30, 40, 50, 60, 70, 80, 90, 100, 110 or 120° C. The temperature is preferably from 15 to 120° C., particularly preferably from 20 to 100° C., and, for example, from 40 to 100° C. or from 70 to 90° C. The temperature is applied, for example, using IR radiation emitters.

After the coating step, the solvent still present is preferably removed from the coating. This can be effected, for example, by means of simple evaporation in air or a suitable inert gas such as nitrogen. The removal of the solvent may be facilitated by heating and/or suitable gas flow and/or applying a vacuum. The evaporation can be facilitated by, for example, heating coated objects in a drying oven or blowing a heated gas flow onto them. The methods can also be combined, for example by drying in a circulating drying oven or a drying channel. Furthermore, the coating can, for the purpose of removing the solvent, also be heated by means of radiation, in particular IR radiation. Any type of broad-band IR radiation emitter, for example NIR, MIR or NIR radiation emitters can be used for this purpose. However, it is also possible, for example, to use IR lasers. These radiation sources are available commercially in a variety of radiation geometries.

The skilled person will determine the temperature and the drying time during the course of the drying. A drying temperature of from 30 to 130° C., preferably of from 50 to 120° C., particularly preferably of from 70 to 110° C., very particularly preferably of from 75 to 105° C., and, for example, from 85 to 100° C., has proved to be of value (temperatures noted refer to the temperature of the coating itself). The temperature in a dryer can, of course, also be higher. The drying time generally is inversely proportional to the drying temperature.

The temperature treatment during the course of the coating, and the drying, can advantageously be combined with each other. Thus, a surface can, for example, be initially treated with a diluted solution of the amphiphilic protein at room temperature and subsequently dried and tempered at elevated temperatures. In a preferred embodiment of the method, an elevated temperature is applied at least in one of the two “treatment” and “drying” steps. A temperature which is higher than room temperature is preferably applied in both steps.

By using the method according to the invention to treat the surface, it is possible to obtain a surface coated with the protein, which comprises the material of the surface and the protein layer which is located immediately on top of it. The protein layer exhibits at least one protein, e.g. hydrophobin, and, if appropriate, other constituents of the formulation. In this connection, the entire surface, or only a part of the surface, can be covered with hydrophobin. The quality can be assessed by means of a variety of methods, for example by means of the contact angle measurement which has already been mentioned. The contact angle changes markedly especially when coating with hydrophobins. Other methods are known to the skilled person from the prior art (e.g. “AFM” atomic force microscopy for directly detecting the protein layer on the surface).

On top of the protein layer, the next layer of functional material is applied by known methods, e.g. solvent processing, coating or printing methods as described above for application of the protein layer. The protein assures improved wetting, and the interlayer thus obtained thereby assures good adhesion of both adjacent layers.

Typically, the amphiphilic protein layer is placed according to the present process between substrate and dielectric layer, between substrate and semiconducting layer, between substrate and conducting layer (such as metal layer, conducting metal oxide layer or conducting polymer layer), between dielectric and semiconducting layer, between dielectric and conducting layer (such as metal layer, conducting metal oxide layer or conducting polymer layer), between semiconducting and conducting layer (such as metal layer, conducting metal oxide layer or conducting polymer layer), between two adjacent semiconducting layers, e.g. of opposite type (p- and n-type, such as used as active layer in certain solar cells.

In some preferred embodiments, the protein interlayer of the invention is applied

a) on the substrate, followed by a layer of the dielectric material, the semiconductor material or a conductor material;
b) on a dielectric layer, followed by a layer of the conductor material or the semiconducting material;
c) on a semiconducting layer, followed by a layer of the conductor material or the dielectric material;
d) on a conducting layer, followed by a layer of the dielectric material or the semiconducting material.

Many classes of semiconducting materials are available in organic electronics. Of importance are semiconducting polymers such as polythiophenes (e.g. P3HT explained further below) and copolymers based on diketopyrrolopyrrol (DPP). In general, semiconducting polymers are conjugated systems comprising unsaturated or aromatic heterocyclics as monomer units, which may be substituted or unsubstituted. Typical examples for such unsaturated or aromatic heterocyclic units are thiophene, pyrrol, furan, ketopyrrol, and annellated combinations thereof. Of special importance are DPP polymers and copolymers thereof with thiophenes, such as compounds of the formula

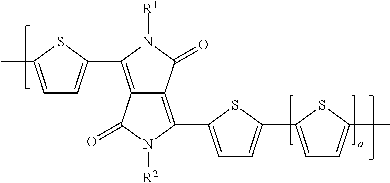

wherein a is e.g. 1 to 3 and R1, R2 each are alkyl, as disclosed in WO10049321 (see especially examples thereof).

Other semiconductor materials showing improved adhesion when in contact with the protein interlayer of the invention include single molecules (such as polycyclic aromatics described in WO07/068,618 and publications cited therein), or their mixtures with polymers.

For example, the semi-conductor component can be prepared from one or more compounds and/or polymers as described in U.S. Pat. No. 6,585,914, U.S. Pat. No. 6,608,323, U.S. Pat. No. 6,991,749, US 2005/0176970, US 2006/0186401, US 2007/0282094, US 2008/0021220, US 2008/0167435, US 2008/0177073, US 2008/0185555, US 2008/1085577 and US 2008/0249309. The semi-conductor component also can include inorganic semi-conductor materials such as silicon, germanium, gallium arsenide, metal oxide and the like.

An example for a functional material comprising a semiconductor is the active layer of a solar cell, a typical composition of which comprises a semiconducting polymer (such as a polymer based on diketopyrrolopyrrol [DPP]), which usually serves as electron donor, and a fullerene (such as PCBM), which usually serves as electron acceptor.

Typical organic electronic devices according to the invention contain functional materials selected from dielectrics, organic semiconductors, organic conductors such as conducting polymers, inorganic conductors such as metals, conducting metal oxides.

An example is an electronic device which comprises an anode layer (a), a cathode layer (e), and an active layer (c), e.g. for converting light into electricity. The substrate usually is adjacent either to layer (a) or to layer (c) or (e). Most frequently, the substrate also functions as a support for stabilization against mechanical or environmental damage; it often is adjacent the anode layer (a). Generally, glass or flexible organic films are used as a support. Adjacent to the anode layer (a) is an optional hole-injecting/transport layer (b), and adjacent to the cathode layer (e) is an optional electron-injection/transport layer (d). Layers (b) and (d) are examples of charge transport layers.

The active layer (c) may contain a host material, which is typically used to aid charge transport within the active layer (c). The active layer (c) can be a small molecule active material.

Active layer (c) may comprise a single material that combines electron transport and further properties such as absorption/emission. Whether the absorptive/emissive material is a dopant or a major constituent, the active layer may comprise other materials, such as dopants that tune the activity of the absorptive/emissive material. Active layer (c) may include a plurality of absorptive/emissive materials capable of, in combination. Examples of host materials include Alga, CBP and mCP.

The active layer (c) can be applied from solutions by any conventional technique, including spin coating, casting, microgravure coating, roll-coating, wire bar-coating, dip-coating, spray-coating, and printing techniques such as screen-printing, flexography, offset-printing, gravure-printing and ink-jet printing. The active organic materials may also be applied directly by vapor deposition processes, depending upon the nature of the materials.

The solvent used in the solution processing method is not particularly limited and preferable are those which can dissolve or uniformly disperse the materials. Preferably the materials may be dissolved in a solvent, the solution deposited onto a substrate, and the solvent removed to leave a solid film. Any suitable solvents may be used to dissolve the ionic compounds, provided it is inert, may dissolve at least some material and may be removed from the substrate by conventional drying means (e.g. application of heat, reduced pressure, airflow, etc.). Suitable organic solvents include, but are not limited to, are aromatic or aliphatic hydrocarbons, halogenated such as chlorinated hydrocarbons, esters, ethers, ketones, amide, such as chloroform, dichloroethane, tetrahydrofuran, toluene, xylene, ethyl acetate, butyl acetate, methyl ethyl ketone, acetone, dimethyl formamide, dichlorobenzene, chlorobenzene, propylene glycol monomethyl ether acetate (PGMEA), and alcohols, and mixtures thereof. Also water and mixtures with water miscible solvents are possible.

Optional layer (d) can function both to facilitate electron injection/transport, and also serve as a buffer layer or confinement layer to prevent quenching reactions at layer interfaces. More specifically, layer (d) may promote electron mobility and reduce the likelihood of a quenching reaction if layers (c) and (e) would otherwise be in direct contact. Examples of materials for optional layer (d) include metal-cheated oxinoid compounds (e.g., tris(8-hydroxyquinolato)aluminum (Alq3) or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like; azole compounds (e.g., 2-(4-biphenylyl)-5-(4-t-butylphenyl)-1,3,4-oxadiazole (“PBD”) or the like, 3-(4-biphenylyl)-4-phenyl-5-(4-t-butylphenyl)-1,2,4-triazole (“TAZ”) or the like; other similar compounds; or any one or more combinations thereof. Alternatively, optional layer (d) may be inorganic and comprise BaO, LiF, Li₂O, or the like.

The electron injection/transport layer (d) can be formed using any conventional means, including spin-coating, casting, and printing, such as gravure printing. The layer can also be applied by ink jet printing, thermal patterning, or chemical or physical vapor deposition.

The anode layer (a) is an electrode that is more efficient for injecting holes compared to the cathode layer (e).

The conducting layer may also be an organic conductor. Typical conductor materials showing improved adhesion when in contact with the protein interlayer of the invention are conducting polymers such as polyaniline, polypyrrole, polythiophene, or PE-DOT:PSS, which are typically applied as aqueous solutions or dispersions. The conductor layer may also a metal layer, e.g. applied by physical vapour deposition. Conductors functioning as hole-transport layer may also be used adjacent to the electrode, e.g. the anode. Both hole transporting small molecule compounds and polymers can be used.

Commonly used hole transporting molecules include: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), α-phenyl-4-N,N-diphenylaminostyrene (TPS), p-(diethylamino)benzaldehydediphenylhydrazone (DEH), triphenylamine (TPA), bis[4-(N,N-diethylamino)-2-methylphenyl](4-methylphenyl)methane (M PMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis (4-methylphenyl)-(1,1′-biphenyl)-4,4′-diamine (TTB), 4,4′-N,N-dicarbazole-biphenyl (CBP), N,N-dicarbazoyl-1,4-dimethene-benzene (DCB), porphyrinic compounds, and combinations thereof.

Commonly used hole transporting polymers are polyvinylcarbazole, (phenylmethyl) polysilane, poly(3,4-ethylendioxythiophene) (PEDOT), and polyaniline. Hole-transporting polymers can be obtained by doping hole-transporting molecules such as those mentioned above into polymers such as polystyrene and polycarbonate.

The hole-injection/transport layer (b) can be formed using any conventional means, including spin-coating, casting, and printing, such as gravure printing. The layer can also be applied by ink jet printing, thermal patterning, or chemical, or physical vapor deposition.

Usually, the anode layer (a) and the hole-injection/transport layer (b) are patterned during the same lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet-chemical or dry-etching techniques. Other processes for patterning that are well known in the art can also be used. When the electronic devices are located within an array, the anode layer (a) and hole injection/transport layer (b) typically are formed into substantially parallel strips having lengths that extend in substantially the same direction.

Conducting layers include materials containing a metal, mixed metal, alloy, metal oxide or mixed-metal oxide. Suitable metal elements include the Groups 4, 5, 6, and 8-11 transition metals. If the layer is to be light transmitting, mixed-metal oxides of Groups 12, 13 and 14 metals, such as indium-tin-oxide, may be used. Some non-limiting, specific examples of materials for a conducting layer, which usually functions as the device's electrode, include indium-tin-oxide (“ITO”), aluminum-tin-oxide, gold, silver, copper, nickel, and selenium.

Metal conducting layers are often formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering (e.g., ion beam sputtering), e-beam evaporation, and resistance evaporation. Specific forms of physical vapor deposition include rf magnetron sputtering or inductively-coupled plasma physical vapor deposition (“ICP-PVD”). These deposition techniques are well-known within the semiconductor fabrication arts.

The cathode layer (e) is an electrode that is particularly efficient for injecting electrons or negative charge carriers. The cathode layer (e) can be any metal or nonmetal having a lower work function than the first electrical contact layer (in this case, the anode layer (a)). Materials for the second electrical contact layer can be selected from alkali metals of Group 1 (e.g., Li, Na, K, Rb, Cs), the Group 2 (alkaline earth) metals, the Group 12 metals, the rare earths, the lanthanides (e.g., Ce, Sm, Eu, or the like), and the actinides. Materials, such as aluminum, indium, calcium, barium, yttrium, and magnesium, and combinations thereof, may also be used. Li-containing organometallic compounds, LiF, and Li2O can also be deposited between the organic layer and the cathode layer to lower the operating voltage. Specific non-limiting examples of materials for the cathode layer (e) include barium, lithium, cerium, cesium, europium, rubidium, yttrium, magnesium, or samarium.

The cathode layer (e) is usually formed by a chemical or physical vapor deposition process. In general, the cathode layer will be patterned, as discussed above in reference to the anode layer (a) and optional hole injecting layer (b). If the device lies within an array, the cathode layer (e) may be patterned into substantially parallel strips, where the lengths of the cathode layer strips extend in substantially the same direction and substantially perpendicular to the lengths of the anode layer strips.

Each functional layer may be made up of more than one layer. For example, the cathode layer may comprise a layer of a Group I metal and a layer of aluminum. The Group I metal may lie closer to the active layer (c), and the aluminum may help to protect the Group I metal from environmental contaminants, such as water.

Although not meant to limit, the different layers may have the following range of thicknesses: inorganic anode layer (a), usually no greater than approximately 500 nm, for example, approximately 50-200 nm; optional hole-injecting layer (b), usually no greater than approximately 100 nm, for example, approximately 50-200 nm; active layer (c), usually no greater than approximately 100 nm, for example, approximately 10-80 nm; optional electron-injecting layer (d), usually no greater than approximately 100 nm, for example, approximately 10-80 nm; and cathode layer (e), usually no greater than approximately 1000 nm, for example, approximately 30-500 nm. If the anode layer (a) or the cathode layer (e) needs to transmit at least some light, the thickness of such layer may not exceed approximately 100 nm.

Flexible plastics materials as substrates are usually films or sheets (laminated or non-laminated), which often are transparent. Materials useful as substrates are, for example, selected from organic polymers described in US-6117997 col. 11, line 64, to col. 15, line 43, especially in GB-A-2367824 page 8, last paragraph, to page 10, paragraph 3. The respective passages are hereby incorporated by reference. Especially preferred substrate materials are polyesters like polyethyleneterephthalate (PET), Polyethylennaphthalate (PEN), polyamides, polyacrylics, polystyrenics. Also possible is coated paper, whose coating layer is, for example, from one of the polymers listed above for substrate materials, or is a polyolefin such as polyethylene or polypropylene. In general, plastics materials for use as the substrate may comprise polymer classes as listed below:

1. Polymers of monoolefins and diolefins, for example polypropylene, polyisobutylene, polybut-1-ene, poly-4-methylpent-1-ene, polyisoprene or polybutadiene, as well as polymers of cycloolefins, for instance of cyclopentene or norbornene, polyethylene (which optionally can be crosslinked), for example high density polyethylene (HDPE), high density and high molecular weight polyethylene (HDPE-HMW), high density and ultrahigh molecular weight polyethylene (HDPE-UHMW), medium density polyethylene (MDPE), low density polyethylene (LDPE), linear low density polyethylene (LLDPE), (VLDPE) and (ULDPE).
2. Mixtures of the polymers mentioned under 1), for example mixtures of polypropylene with polyisobutylene, polypropylene with polyethylene (for example PP/HDPE, PP/LDPE) and mixtures of different types of polyethylene (for example LDPE/HDPE).
3. Copolymers of monoolefins and diolefins with each other or with other vinyl monomers, for example ethylene/propylene copolymers, linear low density polyethylene (LLDPE) and mixtures thereof with low density polyethylene (LDPE), propylene/but-1-ene copolymers, propylene/isobutylene copolymers, ethylene/but-1-ene copolymers, ethylene/hexene copolymers, ethylene/methylpentene copolymers, ethylene/heptene copolymers, ethylene/octene copolymers, propylene/butadiene copolymers, isobutylene/isoprene copolymers, ethylene/alkyl acrylate copolymers, ethylene/alkyl methacrylate copolymers, ethylene/vinyl acetate copolymers and their copolymers with carbon monoxide or ethylene/acrylic acid copolymers and their salts (ionomers) as well as ter-polymers of ethylene with propylene and a diene such as hexadiene, dicyclopentadiene or ethylidene-norbornene; and mixtures of such copolymers with one another and with polymers mentioned in 1) above, for example polypropylene/ethylene-propylene copolymers, LDPE/ethylene-vinyl acetate copolymers (EVA), LDPE/ethylene-acrylic acid copolymers (EAA), LLDPE/EVA, LLDPE/EAA and alternating or random polyalkylene/carbon monoxide copolymers and mixtures thereof with other polymers, for example polyamides.
4. Hydrocarbon resins (for example C₅-C₉) including hydrogenated modifications thereof (e.g. tackifiers) and mixtures of polyalkylenes and starch.
5. Polystyrene, poly(p-methylstyrene), poly(α-methylstyrene).
6. Copolymers of styrene or α-methylstyrene with dienes or acrylic derivatives, for example styrene/butadiene, styrene/acrylonitrile, styrene/alkyl methacrylate, styrene/butadiene/alkyl acrylate, styrene/butadiene/alkyl methacrylate, styrene/maleic anhydride, styrene/acrylonitrile/methyl acrylate; mixtures of high impact strength of styrene copolymers and another polymer, for example a polyacrylate, a diene polymer or an ethylene/propylene/diene terpolymer; and block copolymers of styrene such as styrene/butadiene/styrene, styrene/isoprene/styrene, styrene/ethylene/butylene/styrene or styrene/ethylene/propylene/styrene.
7. Graft copolymers of styrene or α-methylstyrene, for example styrene on polybutadiene, styrene on polybutadiene-styrene or polybutadiene-acrylonitrile copolymers; styrene and acrylonitrile (or methacrylonitrile) on polybutadiene; styrene, acrylonitrile and methyl methacrylate on polybutadiene; styrene and maleic anhydride on polybutadiene; styrene, acrylonitrile and maleic anhydride or maleimide on polybutadiene; styrene and maleimide on polybutadiene; styrene and alkyl acrylates or methacrylates on polybutadiene; styrene and acrylonitrile on ethylene/propylene/diene terpolymers; styrene and acrylonitrile on polyalkyl acrylates or polyalkyl methacrylates, styrene and acrylonitrile on acrylate/butadiene copolymers, as well as mixtures thereof with the copolymers listed under 6), for example the copolymer mixtures known as ABS, MBS, ASA or AES polymers.
8. Halogen-containing polymers such as polychloroprene, chlorinated rubbers, chlorinated and brominated copolymer of isobutylene-isoprene (halobutyl rubber), chlorinated or sulfochlorinated polyethylene, copolymers of ethylene and chlorinated ethylene, epichlorohydrin homo- and copolymers, especially polymers of halogen-containing vinyl compounds, for example polyvinyl chloride, polyvinylidene chloride, polyvinyl fluoride, polyvinylidene fluoride, as well as copolymers thereof such as vinyl chloride/vinylidene chloride, vinyl chloride/vinyl acetate or vinylidene chloride/vinyl acetate copolymers.
9. Polymers derived from α,β-unsaturated acids and derivatives thereof such as polyacrylates and polymethacrylates; polymethyl methacrylates, polyacrylamides and polyacrylonitriles, impact-modified with butyl acrylate.
10. Copolymers of the monomers mentioned under 9) with each other or with other unsaturated monomers, for example acrylonitrile/butadiene copolymers, acrylonitrile/alkyl acrylate copolymers, acrylonitrile/alkoxyalkyl acrylate or acrylonitrile/vinyl halide copolymers or acrylonitrile/alkyl methacrylate/butadiene terpolymers.
11. Polymers derived from unsaturated alcohols and amines or the acyl derivatives or acetals thereof, for example polyvinyl alcohol, polyvinyl acetate, polyvinyl stearate, polyvinyl benzoate, polyvinyl maleate, polyvinyl butyral, polyallyl phthalate or polyallyl melamine; as well as their copolymers with olefins mentioned in 1) above.
12. Homopolymers and copolymers of cyclic ethers such as polyalkylene glycols, polyethylene oxide, polypropylene oxide or copolymers thereof with bisglycidyl ethers.
13. Polyacetals such as polyoxymethylene and those polyoxymethylenes which contain ethylene oxide as a comonomer; polyacetals modified with thermoplastic polyurethanes, acrylates or MBS.
14. Polyphenylene oxides and sulfides, and mixtures of polyphenylene oxides with styrene polymers or polyamides.
15. Polyurethanes derived from hydroxyl-terminated polyethers, polyesters or polybutadienes on the one hand and aliphatic or aromatic polyisocyanates on the other, as well as precursors thereof.
16. Polyamides and copolyamides derived from diamines and dicarboxylic acids and/or from aminocarboxylic acids or the corresponding lactams, for example polyamide 4, polyamide 6, polyamide 6/6, 6/10, 6/9, 6/12, 4/6, 12/12, polyamide 11, polyamide 12, aromatic polyamides starting from m-xylene diamine and adipic acid; polyamides prepared from hexamethylenediamine and isophthalic or/and terephthalic acid and with or without an elastomer as modifier, for example poly-2,4,4,-trimethylhexamethylene terephthalamide or poly-m-phenylene isophthalamide; and also block copolymers of the aforementioned polyamides with polyolefins, olefin copolymers, ionomers or chemically bonded or grafted elastomers; or with polyethers, e.g. with polyethylene glycol, polypropylene glycol or polytetramethylene glycol; as well as polyamides or copolyamides modified with EPDM or ABS; and polyamides condensed during processing (RIM polyamide systems).
17. Polyureas, polyimides, polyamide-imides, polyetherimids, polyesterimids, polyhydantoins and polybenzimidazoles.
18. Polyesters derived from dicarboxylic acids and diols and/or from hydroxycarboxylic acids or the corresponding lactones, for example polyethylene terephthalate, polybutylene terephthalate, poly-1,4-dimethylolcyclohexane terephthalate, polyalkylene naphthalate (PAN) and polyhydroxybenzoates, as well as block copolyether esters derived from hydroxyl-terminated polyethers; and also polyesters modified with polycarbonates or MBS.
19. Polycarbonates and polyester carbonates.
20. Polysulfones, polyether sulfones and polyether ketones.
21. Natural polymers such as cellulose, rubber, gelatin and chemically modified homologous derivatives thereof, for example cellulose acetates, cellulose propionates and cellulose butyrates, or the cellulose ethers such as methyl cellulose; as well as rosins and their derivatives.
22. Blends of the aforementioned polymers (polyblends), for example PP/EPDM, Polyamide/EPDM or ABS, PVC/EVA, PVC/ABS, PVC/MBS, PC/ABS, PBTP/ABS, PC/ASA, PC/PBT, PVC/CPE, PVC/acrylates, POM/thermoplastic PUR, PC/thermoplastic PUR, POM/acrylate, POM/MBS, PPO/HIPS, PPO/PA 6.6 and copolymers, PA/HDPE, PA/PP, PA/PPO, PBT/PC/ABS or PBT/PET/PC.

The dielectric materials in the present organic electronic device are generally selected from classes of materials and material combinations known in the art of electronics for the purpose. The dielectric materials often comprise synthetic polymers, usually homopolymers or copolymers consisting of 2-4 different monomer units e.g. including the polymer classes 1-19 mentioned above for the substrate materials; dielectrics typically belong to the classes of vinyl polymers, polyimides, polycarbonates, polyesters, polyurethanes, polyamides, polyethers. The dielectric materials may combine these synthetic polymers with inorganic components and/or further organic (mono- or oligomeric) components.

Typical dielectric materials showing improved adhesion when in contact with the protein interlayer of the invention are acrylic polymers such as PMMA, styrene based polymers such as PS, Poly-alpha-methylstyrene; of special importance are fluorinated polymer dielectrics (e.g. Cytop®, Asahi Glass co., Wilmington, Del.; and Teflon® AF, Dupont, Wilmington, Del.), poly(isobutylene), poly(vinylphenol-co40-methylmethacrylate), poly(vinylalcohol), poly(propylene), poly(vinylchloride), polycyanopulluane, poly(vinylphenyl), poly(vinylcyclohexane), benzocyclobutane-based polymers, poly(methylmethacrylate), poly(styrene-co-butadiene), poly(cyclohexylmethacrylate), poly(MMA-co-S) (copolymer of methylmethacrylate and styrene), poly-(methoxystyrene) (PMeOS), poly(MeOS-co-S) (copolymer of methoxystyrene and styrene), poly(acetoxystyrene) (PAcOS), poly(AcOS-co-S) (copolymer 5 of acetoxystyrene and styrene), poly(S-co-vinyltoluene) (copolymer of styrene and vinyltoluene), polysulfones, poly(vinylpyridine), poly(vinylidenfluoride), polyacrylonitrile, poly(4-vinylpyridine), poly(2-ethyl-2-oxazoline), poly(chlorotrifluoroethylene), polyvinylpyrrolidone and poly(pentafluorostyrene); see also materials disclosed in WO03/052841 page 8, lines 2 to 15. Preferred are “low-k” dielectric materials (with k standing for the dielectric constant). Further useful materials for dielectric layers are compiled in the following table:

Fluorinated para-xylene
Fluoropolyarylether
Fluorinated polyimide
Polystyrene
Poly (α-methyl styrene)
Poly (α-vinylnaphtalene)
Poly (vinyltoluene)
Polyethylene
cis-polybutadiene
Polypropylene
Polyisoprene
Poly (4-methyl-1-pentene)
Poly (tetrafluoroethylene)
Poly (chorotrifluoroethylene)
Poly (2-methyl-1,3-butadiene)
Poly (p-xylylene)
Poly (α-α-α′-α′ tetrafluoro-p-xylylene)
Poly [1,1-(2-methyl propane) bis (4-phenyl)
carbonate]
Poly (cyclohexyl methacrylate)
Poly (chlorostyrene)
Poly (2,6-dimethyl-1,4-phenylene ether)
Polyisobutylene
Poly (vinyl cyclohexane)
Poly(arylene ether)
Polyphenylene

Electrochromics/electrochromic materials for use as functional layer in organic electronic devices of the invention generally are materials known in the art. Electrochromes (electrochromic materials) can be classified in different groups depending on their physical state at room temperature. Type I electrochromic materials are soluble and remain in the solution during usage. Type II electrochromic materials are soluble in their neutral state and form a solid on the electrode after electron transfer, whereas type III electrochromic materials are solid and remain solid during usage. Three big groups of electrochromes are popular in making electrochromic devices (ECD's): metal oxide films (inorganic type III), conducting polymers (organic type III) and molecular dyes (type I). Especially preferred for use as a functional layer according to the present invention are electrochromic polymers as disclosed in WO 03/046106, especially on pages 16-17 and in the examples, which passages are hereby incorporated by reference.

The following test methods and examples are for illustrative purposes only and are not to be construed to limit the instant invention in any manner whatsoever. Room temperature (r.t. or RT) depicts a temperature in the range 20-25° C.; over night denotes a time period in the range 12-16 hours. Percentages are by weight, temperatures by degrees Celsius (centigrade) unless otherwise indicated.

Abbreviations used in the examples or elsewhere:
BSA bovine serum albumine (Fluka)
IPA isopropanol
ITO indium tin oxide
P3HT poly-3-hexyl-thiophene (semiconducting polymer of regioregularity >98%, obtainable from BASF)
PEDOT:PSS poly(3,4-ethylenedioxythiophene)-polystyrenesulfonate (conducting polymer available from H.C. Starck)
PET polyethyleneterephthalate
PMMA polymethylmethacrylate
PP polypropylene
rpm rounds per minute
RT room temperature
WCA water contact angle (if not otherwise indicated: on PP/static sessile drop) w/w parts or percentage by weight relative to total weight.

### EXPERIMENTAL PART

Hydrophobins used as amphiphilic proteins are as described in WO 07/14897 (see list of SEQ IDs on page 37). Preparation of hydrophobin solutions using those of SEQ ID 20 (hereinafter denoted as A) and SEQ ID 26 (hereinafter denoted as B):

a) From A or B lyophilized powders

In a 250 ml beaker with magnetic stirrer, 0.1 g of the protein powder is dissolved in 99.9 g of deionized water (slow stirring for about 45 minutes at room temperature to avoid foaming). This solution is first filtered through a 5μ disposable filter, then again through a 1 p disposable filter. The solution is used right away within 3 days after preparation.

b) From liquid Protein B

In a 50 ml beaker with magnetic stirrer, 1 g of an aqueous 5% stock solution of protein B is dissolved in 24 g of deionized water (slow stirring for about 10 minutes at room temperature to avoid foaming). This 0.2% solution can be used as such or filtered through a 1μ disposable filter.

c) From diluted stock solution of protein B

In a 50 ml beaker with magnetic stirrer, 2 g of an aqueous 0.5% stock solution of protein B, which solution comprises further additives as described in EP appl. No. 10168712.7 (No. 3 of table 4), is dissolved in 23 g of deionized water (slow stirring for about 10 minutes at room temperature to avoid foaming). This 0.04% solution can be used as is or filtered through a 1μ disposable filter.

### Application of Hydrophobin Solution on a Substrate

The solutions prepared following the procedures described above can be applied using any kind of coating technique like printing (e.g. gravure printing, reverse gravure printing, flexographic printing, inkjet printing), spraying, dipping, doctor blading, curtain coating, slot dye coating, spin coating. For some of these techniques it is favorable to adapt the surface tension of the solution by addition of a suitable additive.

For experimental realization, spin coating, spraying and dipping are chosen, because very homogenous layers can be achieved although a low-viscosity material is used.

When spin coating is used to apply the material, the substrate is mounted on the spin coater, covered with the hydrophobin solution and left without spinning for 10 min to allow the hydrophobin layer to form. This process can be fastened if higher concentrated or warm hydrophobin solutions are used. After 10 min. the sample is spun for 30 min at 3500 rpm acceleration 10000 rpm/s under continuous rinsing with deionized water. When higher concentrated solutions are applied the settling time can be reduced to 1 min. After the spinning has stopped, the sample is dried for 1 min on a hot plate of 90° C. under nitrogen flow. If longer drying is required, the sample can be dried in a vacuum oven at 90° C. for 30 min. The thus obtained treated sample can be readily used for further processing.

When spraying is used to apply the material, the substrate is homogenously covered with the hydrophobin solution by spraying and left to settle for 10 min. to allow the hydrophobinlayer to form. This process can be fastened if higher concentrated or warm hydrophobin solutions are used. Afterwards the access of solution is washed away by rinsing with deionized water. The thus obtained sample is dried in a vacuum oven at 90° C. for 1-30 min. The thus obtained treated sample can be readily used for further processing.

When dipping is used to apply the material, the substrate is dipped into a beaker containing the hydrophobin solution in a way that the surface that should be treated is fully covered. The substrate is left to settle for 10 min to allow the hydrophobin to form. This process can be fastened if higher concentrated or warm hydrophobin solutions are used. The substrate is taken out of the solution, thoroughly rinsed with deionised water and dried in a vacuum oven at 90° C. for 130 min. The thus obtained treated sample can be readily used for further processing.

### Device Fabrication & Testing

### a) Capacitors

The preparation of capacitors is realized following the procedure described below. The dielectric solution is prepared by dissolving 0.6 g of Polymethylmethacrylate (PMMA, Mw=996.000 g/mol) from Aldrich® in 9.4 g of ethyllactate. This solution is spin coated onto clean ITO substrates for 30 s at 3500 rpm (acceleration 10.000 rpm/s) to give films of thickness in the range of 485 nm. ITO glass slides are cleaned by sonication in organic solvents before use. After the spin-coating step, the resulting dielectric films are dried in an oven at 160° C. for 60 minutes. Depending on the dielectric formulation used, drying time and temperature can be significantly reduced. Onto this dielectric film the hydrophobin solution is applied by any of the techniques mentioned above, in this specific example by spin coating a 0.1% solution obtained from the powder (a). The applied hydrophobin layer is dried for 1 min at 90° C. on a hot plate in air. Gold is evaporated through a shadow mask on top of the hydrophobin layer to complete the capacitor with top electrodes. Leakage current density through the dielectric layer is determined using an Agilent 4155C parameter analyzer (2V steps/hold time 2000 ms/integration time=200 ms/delay time=600 ms; the source electrode is connected with the ITO electrode and the Gate electrode with the + or − potential with the gold contact on top). Table 1 shows the leakage current density I/A of the untreated sample (comparison) and the sample containing the hydrophobin layer of the invention as a function of the voltage (U) and the field (MV/cm) applied. The leak current is practically identical for both devices; the hydrophobin layer gives no negative impact on the device's performance.

TABLE 1
Leakage currrent density as a function of the electric field for spin-
coated ITO-PMMA-Au (right, comparison) and
ITO-PMMA-hydrophobin-Au (left) capacitors

| | U/d | I/A (inv) | I/A (comp) |
|---|---|---|---|
| U [V] | [MV/cm] | [A/cm²] | [A/cm²] |
| 0 | 0.00 | 1.15E−11 | 1.15E−11 |
| 4 | 0.08 | 4.18E−10 | 4.10E−10 |
| 8 | 0.16 | 5.91E−10 | 5.52E−10 |
| 12 | 0.25 | 6.89E−10 | 6.57E−10 |
| 16 | 0.33 | 7.50E−10 | 7.32E−10 |
| 20 | 0.41 | 8.17E−10 | 7.90E−10 |
| 40 | 0.82 | 9.89E−10 | 9.32E−10 |
| 60 | 1.24 | 1.12E−09 | 1.06E−09 |
| 80 | 1.65 | 1.23E−09 | 1.16E−09 |
| 100 | 2.06 | 1.35E−09 | 1.28E−09 |
| 0 | 0.00 | 1.15E−11 | 1.15E−11 |
| −4 | −0.08 | 3.52E−10 | 3.91E−10 |
| −8 | −0.16 | 5.24E−10 | 5.68E−10 |
| −12 | −0.25 | 6.24E−10 | 6.80E−10 |
| −16 | −0.33 | 7.17E−10 | 7.32E−10 |
| −20 | −0.41 | 7.43E−10 | 7.89E−10 |
| −40 | −0.82 | 9.43E−10 | 9.55E−10 |
| −60 | −1.24 | 1.04E−09 | 1.08E−09 |
| −80 | −1.65 | 1.17E−09 | 1.17E−09 |
| −100 | −2.06 | 1.29E−09 | 1.28E−09 |

### b) Diodes

The most common function of a diode is to allow an electric current to pass in one direction (called the diode's forward direction) while blocking current in the opposite direction (the reverse direction). Thus, the diode can be thought of as an electronic version of a check valve. This unidirectional behavior is called rectification, and is used to convert alternating current to direct current, and to extract modulation from radio signals in radio receivers. An important characteristic of a diode is therefore the ratio between the current in the on-state and the current in the off-state, which should be as high as possible.

One type of diodes are the so-called Schottky diodes, which are the heart of RF detectors and mixers. The influence of the hydrophobin on the electrical characteristics of such diodes can be tested when comparing devices prepared with and without adhesion aid in the following way: On a substrate of PET foil with evaporated Aluminum, Poly-3-hexyl-thiophene (P3HT) is gravure printed from a 1-1.5 wt % solution of Toluene/Chloroform (1:1 to 1:3). With a printing speed of 0.5 m/s and gravure patterns of 32, 54 and 100 lines/cm smooth films can be obtained. The applied semiconductor layer is dried at 90° C. for 8 s. As next step the hydrophobin solution prepared from the powder as described above is spin coated from for 20 s at a velocity of 2000 rpm and an acceleration of 972 rpm/s. As anode, Polyaniline (PANI, prepn. as described in E. Hrehorova et al., The Properties of Conducting Polymers and Substrates for Printed Electronics, Proc. of the IS&T DF05 Int. Conf. on Digital Fabrication Technologies, Baltimore 2005; available under the trade name ORMECON®) or PEDOT:PSS (Clevios P VP Al 4083 from H.C. Starck) is manually dispensed.

Diode characteristics are investigated using a Keithley® 2612 device. Diodes are classified as functioning when Jon/Joff>20. Results are compiled in the following tables 2-3 (J in A/cm2).

TABLE 2
Characteristics of gravure printed diodes with a
PET-Al/P3HT/PEDOT:PSS architecture with and without
hydrophobin as an interlayer between Al and P3HT.

| | | |
|---|---|---|
| P3HT | P3HT | |
| diode without | diode with | P3HT diode with |
| hydrophobin | hydrophobin B | hydrophobin A |

Grid 32

| | | | |
|---|---|---|---|
| Jon | 0.00077 | 0.00149 | 0.00714 |
| Joff | 0.00001 | 0.00017 | 0.00010 |
| on/off | 159.78 | 193.56 | 731.89 |
| diodes functioning | 5 | 5 | 5 |
| number of diodes | 8 | 5 | 5 |
| quote | 62.5% | 100.0% | 100.0% |

Grid 54

| | | | |
|---|---|---|---|
| Jon | 0.00093 | 0.00414 | 0.00510 |
| Joff | 0.00015 | 0.00020 | 0.00292 |
| on/off | 22.75 | 555.24 | 168.20 |
| diodes functioning | 2 | 5 | 5 |
| number of diodes | 5 | 5 | 8 |
| quote | 40.0% | 100.0% | 62.5% |

Grid 100

| | | |
|---|---|---|
| Jon | 0.00134 | 0.14416 |
| Joff | 0.00065 | 0.00787 |
| on/off | 200.79 | 629.89 |
| diodes functioning | 3 | 2 |
| number of diodes | 5 | 5 |
| quote | 60.0% | 40.0% |

TABLE 3
Typical characteristics of gravure printed diodes with a
PET-Al/P3HT/PANI architecture with and without
hydrophobin as an interlayer between Al and P3HT.

| | | |
|---|---|---|
| P3HT | P3HT | |
| diode without | diode with | P3HT diode with |
| hydrophobin | hydrophobin B | hydrophobin A |

Grid 32

| | | | |
|---|---|---|---|
| Jon | 0.00821 | 0.03956 | 0.04330 |
| Joff | 0.00014 | 0.00001 | 0.00269 |
| on/off | 376.95 | 4311.92 | 3210.03 |
| diodes functioning | 3 | 4 | 5 |
| number of diodes | 5 | 4 | 5 |
| quote | 60.0% | 100.0% | 100.0% |

Grid 54

| | | | |
|---|---|---|---|
| Jon | 0.00183 | 0.06588 | 0.11550 |
| Joff | 0.00001 | 0.00228 | 0.00269 |
| on/off | 675.01 | 2943.44 | 3151.90 |
| diodes functioning | 4 | 4 | 5 |
| number of diodes | 4 | 5 | 5 |
| quote | 100.0% | 80.0% | 100.0% |

As can be seen in Table 2 and Table 3, the application of a hydrophobin interlayer improves the Jon/Joff ratio. This effect does not dependent on the cathode material or the type of protein used, while the yield stays about the same.

### c) Field Effect Transistors

For the fabrication of a top gate bottom contact field effect transistors, PET film with lithographically structured gold electrodes is used as substrate. The hydrophobin can be applied at any interface in the transistor—between substrate and semiconductor, semiconductor and dielectric, as well as between dielectric and gate electrode using the processing conditions mentioned above. For application of the hydrophobin inter-layer between substrate and semiconductor one convenient way of processing is dipping. Onto the thus obtained hydrophobin covered substrate, the DPP semiconductor disclosed in example 2 of WO10049321 (hereinafter denoted as DPP) is applied by spin coating for 30 s from a 0.75% solution in toluene at 1300 rpm, 10.000 rpm/s, followed by drying on a hot plate for 30 s at 90° C. As dielectric layer, a 5% solution of PMMA in ethyl lactate is spincoated for 30 s at 3500 rpm, 10.000 rpm/s and dried at 90° C. on a hot plate before evaporating the Au gate electrode through a shadow mask on top. All procedures are ideally performed in a clean room in ambient atmosphere. FIG. 2 and FIG. 3 show the FET characteristics measured in ambient with a Keithley 4200 semiconductor parameter analyzer.

For application of the hydrophobin interlayer between semiconductor and dielectric layer one convenient way of processing is spin coating. Therefore a 0.75% solution of DPP in toluene is spun onto a PET film with lithographically structured gold source drain electrodes by spin coating for 30 s at 1300 rpm, 10.000 rpm/s, followed by drying on a hot plate for 30 s at 90° C. The hydrophobin layer is also applied by spincoating as described above. As dielectric layer a 5% solution of PMMA in ethyl lactate is spin-coated for 30 s at 3500 rpm, 10.000 rpm/s and dried at 90° C. on a hot plate before evaporating the Au gate electrode through a shadow mask on top. All procedures are ideally performed in a clean room in ambient. FIG. 4 and FIG. 5 show the FET characteristics measured in ambient with a Keithley 4200 semiconductor parameter analyzer.

For application of the hydrophobin interlayer between dielectric layer and gate electrodes one convenient way of processing is spin coating. Therefore a 0.75% solution of DPP in toluene is spun onto a PET film with lithographically structured gold source drain electrodes by spin coating for 30 s at 1300 rpm, 10.000 rpm/s, followed by drying on a hot plate for 30 s at 90° C. As dielectric layer a 5% solution of PMMA in ethyl lactate is spincoated for 30 s at 3500 rpm, 10.000 rpm/s and dried at 90° C. on a hot plate. The hydrophobin layer is also applied by spin coating onto the dielectric layer as described above. To complete the field effect transistor the Au gate electrode through a shadow mask on top. All procedures are ideally performed in a clean room in ambient. FIG. 6 show the FET characteristics measured in ambient with a Keithley 4200 semiconductor parameter analyzer.

d) Polymer based bulk heterojunction solar cell

Polymer based bulk heterojunction solar cells containing a hydrophobin B adhesion layer can be realised in the following structure: Al electrode/LiF layer/organic active layer comprising DPP and [70]PCBM/[poly(3,4-ethylenedioxy-thiophene) (PEDOT) in admixture with poly(styrenesulfonic acid) (PSS)]/ITO electrode/glass substrate. The solar cell is made by dipping a glass substrate with pre-patterned ITO into an hydrophobin B solution prepared following the procedure described above. After treatment, rinsing and drying of the substrate, a layer of the PEDOT-PSS is spin coated on top to give a thickness of about 70 nm. Then a 1:1.5 mixture of the DPP compound (1% by weight): [70]PCBM (a substituted C70 fullerene from Sigma-Aldrich®) is spin coated from ortho-dichloro benzene to yield an active layer of about 100 nm thickness. LiF and Al are sublimed under high vacuum through a shadow-mask.

The solar cell is measured under a solar light simulator (irradiance 100 mW/cm2). The current is estimated under AM1.5 G conditions with the External Quantum Efficiency (EQE) graph. This leads to a value of Jsc=mA/cm2, FF= and Voc=V for an estimated overall efficiency of %.

e) Influence of an hydrophobin layer on the adhesion of a semiconductor on a substrate Printed P3HT layers easily lift off from a PET substrate when the adhesion is not sufficient.

This occurs especially when different layers are printed one after the other by rewinding and unwinding the roll after each applied layer. In order to improve the adhesion of the P3HT hydrophobin can be brought up on the cathode. As substrate a metalized foil is used on which the hydrophobin can be applied by any of coating techniques, e.g. spin coating from a 0.1% solution made from hydrophobin Gran. at 2000 rpm and an acceleration of 972 rpm/s. After drying the sample for 1 min at 90° C. the semiconductor, e.g. P3HT is printed from a 1% solution of toluene with different gravure patterns between 32 lines/cm and 120 lines/cm at a speed of 0.5 m/s. The semiconductor layer is dried at 90° C. for 8 s. Results obtained after coating a PET substrate with P3HT, winding the coated substrate to a roll and unwinding it again are shown in FIG. 1, using hydrophobin interlayer (left) and without hydrophobin interlayer (right).

Quantification of Adhesion with “Scotch Tape Test”:

The improvement of adhesion is assessed as follows: P3HT is spin coated on a PET film substrate with and without adhesion aid (hydrophobin). Scotch tape is put on top and ripped off in an angle of 180° with a defined force. The P3HT sticking to the tape is washed off and quantified by SEC (size exclusion chromatography) with THF+0.1% trifluoro acetic acid as eluent. The detection is effected with a differential refractometer Agilent 1100, UV-Photometer Agilent 1100 VWD, PSS SLD7000-BI-MwA [UV/254 nm/Agilent]. The amount of P3HT can be calculated with a calibration curve obtained from polystyrene standard from Polymer Laboratories with molecular weights of Mw=580 to Mw=7,500,000, and hexyl benzene (Mw=162). 4 samples with, and 4 samples without adhesion aid are tested. Results: Mean value without hydrophobin is 1.53 μg of P3HT; mean value without hydrophobin is 1.01 μg of P3HT.

### BRIEF DESCRIPTION OF FIGURES

FIG. 1 shows pictures of a P3HT layer after unwinding from a rewinded roll. Clearly, an improved adhesion of the P3HT printed on the hydrophobin adhesion layer can be observed (see example e). Picture left: With adhesion aid on cathode (invention). Picture right: Without adhesion aid on cathode (comparison).

FIG. 1: Transfer curve of a field effect transistor on PET/Au-hydrophobin-DPP-PMMA-Au at Vsd=−20V using hydrophobin solution made from hydrophobin B liquid; semiconductor and PMMA are applied by spincoating whereas hydrophobin is applied by dipping.

FIG. 2: Transfer curve of a field effect transistor on PET/Au-hydrophobin-DPP-PMMA-Au at Vsd=−20V made from hydrophobin solution using hydrophobin B Formula 6; semiconductor and PMMA are applied by spincoating whereas hydrophobin is applied by dipping.

FIG. 3: Transfer curve of a spincoated field effect transistor on PET/Au-DPP-hydrophobin-PMMA-Au at Vsd=−20V using hydrophobin solution made from hydrophobin B liquid.

FIG. 4: Transfer curve of a spincoated field effect transistor on PET/Au-DPP-Hydrophobin-PMMA-Au at Vsd=−20V using Hydrophobin solution made from Hydrophobin B Formula 6.

FIG. 5: Transfer curve of a spincoated field effect transistor on PET/Au-DPP-PMMA-Hydrophobin-Au at Vsd=−20V using Hydrophobin solution made from Hydrophobin B liquid.

FIG. 6: Transfer curve of a spincoated field effect transistor on PET/Au-DPP-PMMA-Hydrophobin-Au at Vsd=−20V using hydrophobin solution made from hydrophobin B Formula 6.

FIG. 7: Transfer curve of a field effect transistor on PET/Au-hydrophobin-DPP-PMMA-Au at Vsd=−20V using hydrophobin solution made from hydrophobin B Formula 6; the semiconductor is applied by inkjet printing whereas hydrophobin is applied by dipping and PMMA is applied by spincoating.

FIG. 8: Transfer curve of a field effect transistor on PET/Au-hydrophobin-DPP-PMMA-Au at Vsd=−20V using hydrophobin solution made from hydrophobin B liquid; the semiconductor is applied by inkjet printing whereas hydrophobin is applied by dipping and PMMA is applied by spincoating.

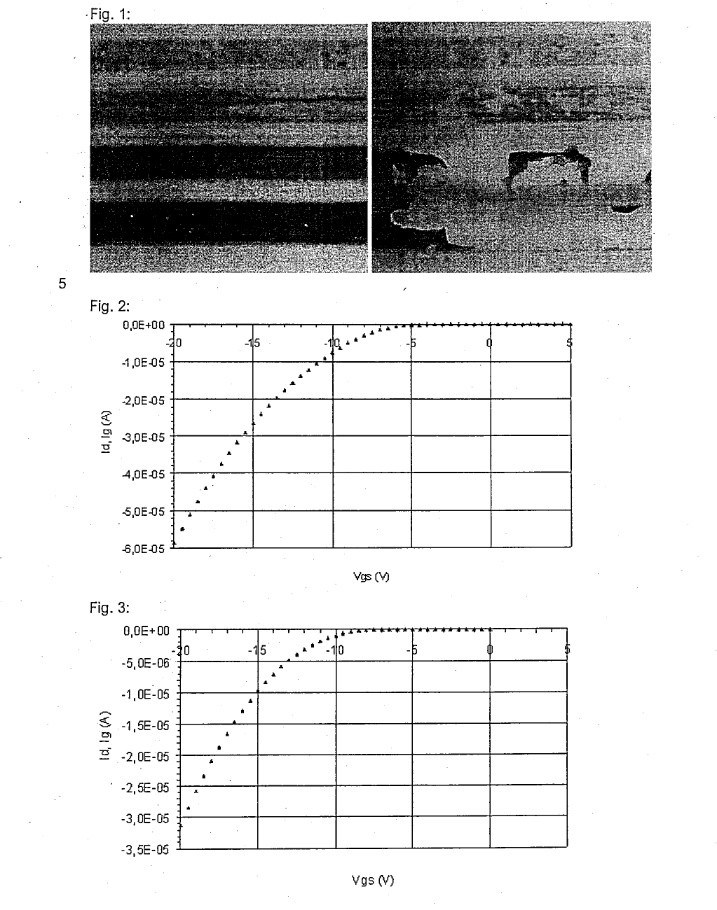

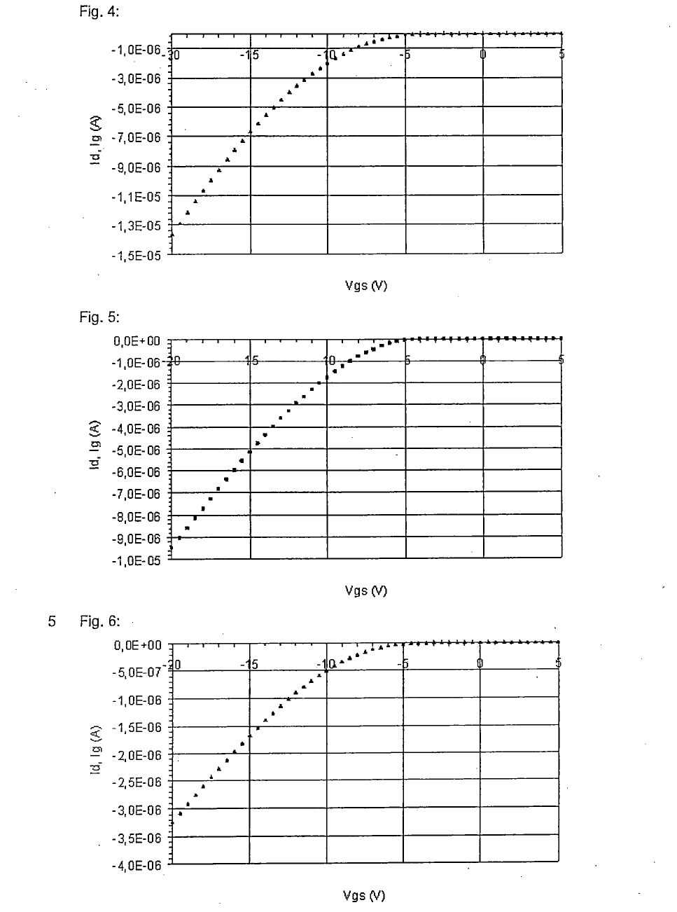

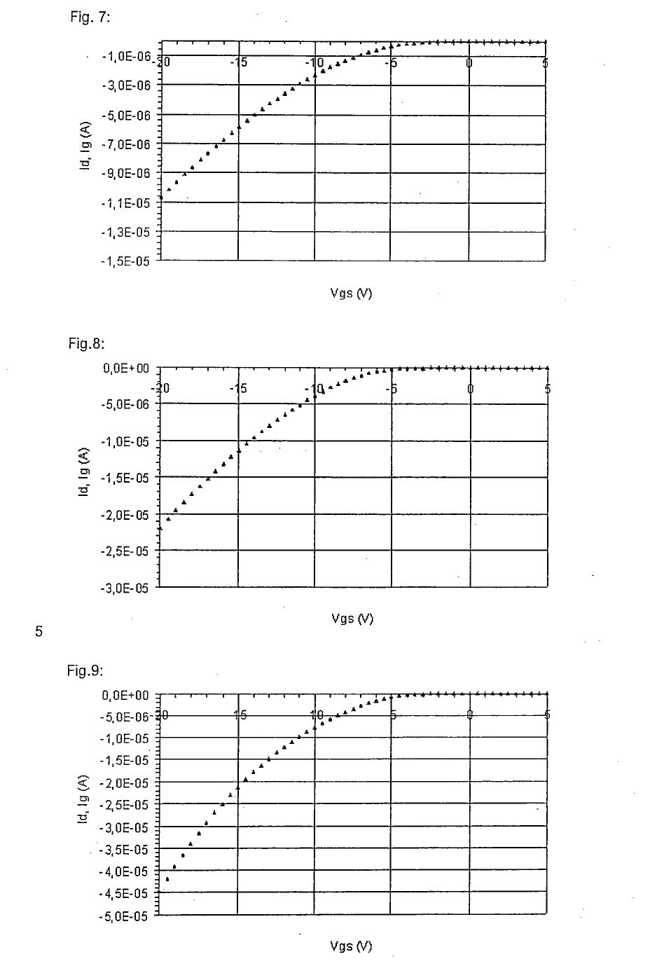

1. A process for preparing an organic electronic device comprising a layer of a suitable functional material on a substrate, the process comprising placing an interlayer of an amphiphilic protein between adjacent layers of the functional material, or between the substrate and an adjacent layer of the functional material.

2. The process of claim 1, wherein the functional material is at least one selected from the group consisting of a semiconductor, a dielectric, an electrochromic, and a conductor.

3. The process of claim 1, wherein the functional material is at least one selected from the group consisting of a semiconductor, a dielectric, and a conductor, wherein the substrate is a flexible plastics material.

4. The process of claim 1, wherein the layer of a suitable functional material, the amphiphilic protein interlayer, or both, is applied by solution processing.

5. The process of claim 1, wherein the amphiphilic protein is applied as an aqueous solution or dispersion, by at least one solution process selected from the group consisting of an ink jet, a screen, a gravure, a reverse gravure, an offset, a flexographic printing method, or by spraying, dipping, doctor blading, curtain coating, slot dye coating, or spin coating.

6. The process of claim 1, wherein the amphiphilic protein interlayer applied is subsequently dried at 20 to 160° C.

7. The process of claim 1, wherein the amphiphilic protein is a hydrophobin.

8. The process of claim 1, wherein the amphiphilic protein interlayer is a molecular monolayer.

9. The process of claim 1, wherein the amphiphilic protein interlayer is placed between the substrate and a dielectric layer, between the substrate and a semiconducting layer, between the substrate and a conducting layer, between a dielectric layer and a semiconducting layer, between a dielectric layer and a conducting layer, between a semiconducting layer and a conducting layer, or between two adjacent semiconducting layers.

10. An organic electronic device obtainable in obtained by the process in claim 1.

11. The organic electronic device of claim 10, comprising a layer of a suitable functional material on a substrate and an interlayer of an amphiphilic protein between adjacent layers of the functional material, or between the substrate and an adjacent layer of the functional material.

12. The organic electronic device of claim 10, wherein the functional material is at least one selected from the group consisting of a dielectric, an organic semiconductor, an electrochromic polymer, an organic conductor, an inorganic conductor, and a conducting metal oxide.

13. The organic electronic device of claim 10, wherein the device comprises the layer of a suitable functional material and the interlayer in a capacitor, a diode, a photodiode, or a thin film transistor.

14. The organic electronic device of claim 13, wherein the device is at least one selected from the group consisting of an integrated circuit, a display, an electrochromic device, a RFID tag, an electroluminiscent device, a photoluminescent device, a backlight of a display, a photovoltaic device, and a solar cell.

15. An amphiphilic protein suitable for the preparation of an organic electronic device comprising a layer of a functional material on a substrate.

16. The process of claim 1, comprising placing the amphiphilic protein interlayer between adjacent layers of the functional material.

17. The process of claim 1, comprising placing the amphiphilic protein interlayer between the substrate and an adjacent layer of the functional material.

18. The process of claim 4, wherein the solution processing comprises at least one selected from the group consisting of an ink-jet, a screen, a gravure, a reverse gravure, an offset, and a flexographic printing method.

19. The process of claim 5, wherein the amphiphilic protein is applied as an aqueous solution or dispersion comprising 0.001 to 1% by weight of the protein.

20. The process of claim 1, wherein the amphiphilic protein layer applied is subsequently dried at 40 to 120° C.
